(19) United States
(12) Patent Application Publication
(10) Pub. No.: US 2024/0381536 A1
(43) Pub. Date: Nov. 14, 2024

(54) ELECTRONIC COMPONENT APPLIQUES

(71) Applicant: Liquid Wire Inc., Portland, OR (US)

(72) Inventor: Mark William Ronay, Portland, OR (US)

(73) Assignee: Liquid Wire Inc., Portland, OR (US)

(21) Appl. No.: 18/777,838

(22) Filed: Jul. 19, 2024

Related U.S. Application Data
(63) Continuation of application No. PCT/US23/61266, filed on Jan. 25, 2023.
(60) Provisional application No. 63/268,791, filed on Mar. 2, 2022.
(60) Provisional application No. 63/302,564, filed on Jan. 25, 2022.

(51) Int. Cl. H05K 1/18; H01L 23/00; H05K 1/11

(52) U.S. Cl. CPC H05K 1/181; H05K 1/115; H01L 24/32; H01L 2224/32225

(57) ABSTRACT

An applique and system includes a substrate having an adhesive property and conductive gel. The conductive gel is contained within the substrate. The conductive gel is configured to electrically couple with a first electronic component and a second electronic component to electrically couple the first electronic component to the second electronic component. The adhesive property of the substrate is configured to adhere at least one of the first electronic component and the second electronic component to the substrate.

### CLAIM OF PRIORITY

This patent application is a continuation of PCT Application No. PCT/US23/61266, filed Jan. 25, 2023, which claims the benefit of priority from U.S. Provisional Patent Application Nos. 63/302,564, filed Jan. 25, 2022, and 63/268,791, filed Mar. 2, 2022, each of which are incorporated by reference herein in their entirety.

### BACKGROUND

Electronic components, from complicated examples, such as integrated circuits and semiconductors generally, to simple examples, such as resistors, capacitors, and the like, are conventionally packaged in industry-standard formats. Such electronic components may therefore have predictable sizes, properties, and arrangements of input/output pins or other contacts and the like. On that basis, such electronic components may be incorporated as discrete components in wider systems and electronic circuits, e.g., by being electrically and mechanically coupled to a printed circuit board (PCB), among a variety of other circumstances and environments.

### BRIEF DESCRIPTION OF THE SEVERAL VIEWS OF THE DRAWINGS

FIG. 1 is an exploded view of an electronic system including an electronic component electrically and mechanically coupled to a PCB with an electronic component applique, in an example embodiment.

FIG. 2 is a cross-sectional depiction of the electronic system, in an example embodiment.

FIG. 3 is an exploded view of an alternative electronic system including the electronic component electrically and mechanically coupled to the PCB 104 with an electronic component applique, in an example embodiment.

FIG. 4 is a cross-sectional depiction of the electronic system, in an example embodiment.

FIG. 5 is an exploded view of an alternative electronic system including an electronic component electrically and mechanically coupled to a PCB with an electronic component applique, in an example embodiment.

FIG. 6 illustrates a sheet of electronic component appliques, in an example embodiment.

FIG. 7A illustrates a roll of electronic component appliques, in an example embodiment.

FIG. 7B illustrates a side profile of a portion of the roll 702, in an example embodiment.

### DETAILED DESCRIPTION

Example methods and systems are directed to an electronic component applique, system, and method. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

Because of the commonality of electronic component packages, it is often the case that different electronic components have the same electronic properties in different packages. For instance, resistors with the same amount of resistance may nonetheless be in significantly different-size packages. Moreover, the manner in which electronic components of different package types electrically and mechanically connect with another component, such as a PCB, may vary significantly dependent on the type of input/output connections the chip package has. This may impact both the capacity of an electronic component to be electrically incorporated into a wider system or circuit as well as the strength of the resultant mechanical connection between the electronic component and the wider system, e.g., the PCB.

The present disclosure generally relates to electronic circuits and more specifically to structures and methods for attaching electronic components to electronic circuits, and for attaching electronic circuits to other electronic circuits, whereby electrical communication is provided between the attached circuits and components. In particular, an electronic component applique has been developed that facilitates the electrical and mechanical coupling of an electronic component to a wider circuit or system. The electronic component applique includes conductive traces that extend through the electronic component applique that align with the input/output pins of an electronic component of a particular package format as well as the layout of connection points in the wider system, such as on the PCB.

The electronic component applique further includes a substrate material that allows the electronic component applique to mechanically bond with the electronic component and the PCB, thereby strengthening the mechanical connection of the electronic component to the PCB. The conductive traces may be made of conductive gel that may be contained by and within the substrate and which, because of the properties of the conductive gel, may maintain the electrical connection between the electronic component and the PCB even when the substrate is adhered to the PCB, e.g., by curing, heating, etc. While the electronic component applique is described here with respect to a PCB, it is to be recognized and understood that discussions of a PCB herein are a non-limiting example and that the electronic component applique may be applied between an electronic component and any other component of a circuit or system.

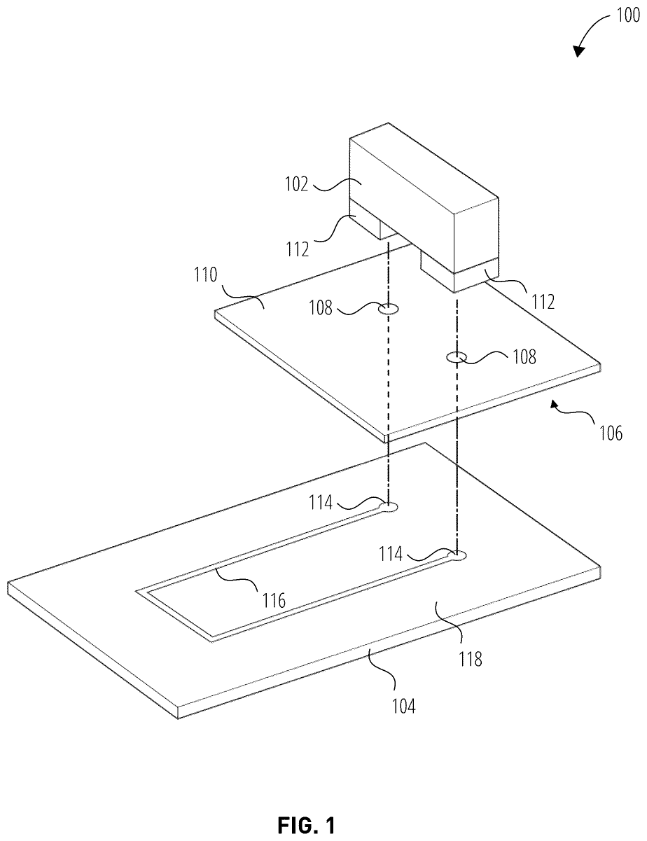

FIG. 1 is an exploded view of an electronic system 100 including an electronic component 102 electrically and mechanically coupled to a PCB 104 with an electronic component applique 106, in an example embodiment. The electronic component 102 is a conventional chip package, but it is to be recognized and understood that the principles disclosed herein may apply to any suitable electronic component that has been or may be developed. Similarly, the PCB 104 is a conventional PCB known in the art, but the principles disclosed herein may be applied to any board, component, or device to which the electronic component 102 may be electrically and mechanically coupled. While the PCB 104 is described specifically herein, it is to be recognized and understood that the PCB 104 may be an electronic component generically. Consequently, the disclosure herein may be understood to refer to a first electronic component as the electronic component 102 and the PCB 104 may be a second electronic component, or that the second electronic component may be any other suitable electronic component.

The electronic component applique 106 includes conductive gel 108 and a substrate 110 configured to secure the conductive gel 108 in a predetermined configuration. In particular, as illustrated the predetermined configuration of the conductive gel 108 is as vias which extend through a thickness of the substrate 110 specifically and the electronic component applique 106 generally to which contacts 112 may be electrically and mechanically coupled. However, as will be illustrated in detail herein, the electronic component applique 106 may optionally include conductive gel in other configurations, including electrical traces and the like.

The conductive gel 108 may be completely surrounded by the substrate 110, e.g., the substrate 110 fully surrounds the conductive gel 108 and prevent or significantly inhibit the conductive gel 108 from migrating laterally from the substrate 110. The conductive gel 108 defines an opening in the substrate 110 that corresponds to a form factor of the electronic component 102 such that the contacts 112 of the electronic component 102 align with the conductive gel 108. In this embodiment, the contacts 112 are shown as input/output pins. In other embodiments (not shown), contacts 112 may be substantially flush with the lower surface of the electronic component 102, such as is common with surface mount components (SMC). Consequently, in an example, a particular electronic component applique 106 may be designed for any electronic component 102 having the same form factor, with different sizes of electronic component applique 106 made for different form factors of different electronic components 102.

The conductive gel 108 further alights with electrical contacts 114 of the PCB 104, allowing the conductive gel 108 to electrically couple each contact 112 of the electronic component 102 to an associated electrical contact 114 of the PCB 104. The PCB 104 further includes a conventional trace 116 positioned on a major surface 118 of the PCB 104. The PCB 104 is highly simplified and it is to be recognized and understood that the PCB 104 may include more than one electronic component 102 and the trace 116 may be one of multiple traces 116 that extend between and among the various electronic components 102.

The substrate 110 may be formed of any of a variety of suitable materials, including but not limited to thermoplastic polyurethane (TPU) film, B-stage resin film, or any other suitable film or material that can contain the conductive gel 108. Additionally or alternatively, a C-stage resin film, an adhesive, a thermoset epoxy-based film may be utilized, where such materials have an adhesive property. Further, combinations of materials may be utilized as the substrate 110, e.g., a polyimide flex PCB-type sheet or film material with an adhesive film applied to attachment surfaces. Moreover, the material of the substrate 110 may provide bonding between the electronic component 102 and the PCB 104. Thus, in such an example, the substrate 110 may be secured to each of the electronic component 102 and PCB 104, with each of the electronic component 102 and PCB 104 providing further containment for the conductive gel 108 to prevent or inhibit migration. In various examples, the electronic component applique 106 may be applied to the electronic component 102 alone, or to the electronic component 102 and the major surface 118 of the PCB 104.

In various examples, the electronic component 102 and/or PCB 104 may have uneven surfaces, including deliberate unevenness or imperfections. In various examples, the electronic component applique 106 may have a thickness and flexibility that allows the electronic component applique 106 to take up such imperfections without breaking bonding between the electronic component applique 106 and the electronic component 102 and/or PCB 104. In an example, the electronic component applique 106 has a thickness of 0.004 inches, but it is to be recognized and understood that any suitable thickness may be implemented that still provides sufficient mechanical coupling between the electronic component 102 and the PCB 104. In some examples, the electronic component applique 106 may have a thickness in the range of about 0.002 inches to about 0.100 inches. Larger applique thicknesses in combination with a soft substrate material characteristic may be particularly beneficial for use on surfaces that have coarse or uneven surfaces.

In various examples, the electronic component applique 106 may be applied to and bonded with one or both of the electronic component 102 and PCB 104 according to any of a variety of methods. In an example, the substrate 110 may be melted prior to or after being applied to the electronic component 102 and/or PCB 104. In an example, the substrate 110 may be cured under pressure and/or heat. Melting may allow the substrate 110 to flow into surface variations of the electronic component 102 and/or PCB 104. Cooling and/or curing the substrate 110 may create a seal between the substrate 110 and the electronic component 102 and/or PCB 104 that may inhibit or prevent migration of the conductive gel 108. Curing operations may be carried out, e.g, through the use of heat or other exemplary methods such as exposure to ultraviolet light, moisture, gases or combinations thereof. Consequently, because the conductive gel 108 and substrate 110 are deformable and/or conformable, the electronic component applique 106 may be applicable to and adaptable to any of a variety of circumstances involving different electronic components 102 and/or PCBs 104.

In various examples, the electronic component applique 106 may optionally additionally include a thin film or other thin isolating material on one or both major surfaces of the electronic component applique 106. In various examples, the thin film may be made from any conventional interface material and may optionally included in the electronic system 100 or may be removed prior to applying the electronic component applique 106 to the electronic component 102 and/or PCB 104. Additionally or alternatively, the PCB 104 may be anodized or coated at the interface with the electronic component applique 106, e.g., via physical vapor deposition, electroplating, etc., with a material that is non-dissolvable in liquid metal. The material may be metal, carbon, industrial diamond, or any other suitable material. The metal may include but not be limited to copper, gold, silver, etc., and may optionally be finished with encapsulation, potting, etc., after attachment to the PCB 104. Moreover, it is noted and emphasized that the PCB 104 is provided by way of example and not limitation, and that the principles disclosed herein apply to any other components or surfaces, including but not limited to electrical contacts that are components of any system or component, battery terminals, etc.

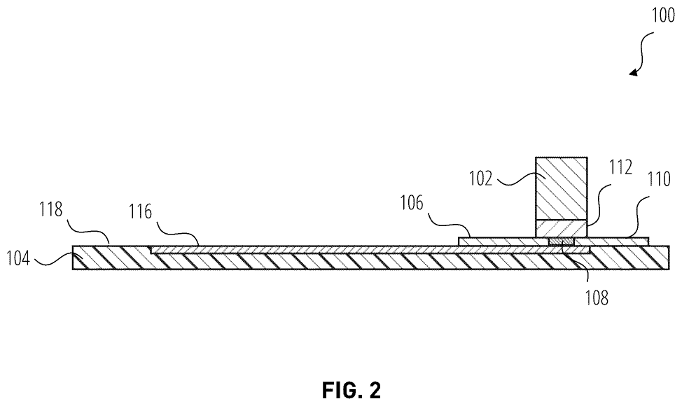

FIG. 2 is a cross-sectional depiction of the electronic system 100, in an example embodiment. As illustrated, the electronic component applique 106 is a single layer construction with the conductive gel 108 formed as vias extending entirely through a thickness of the electronic component applique 106 and substrate 110. Moreover, the vias are entirely filled with the conductive gel 108. The conductive gel 108 thus provides an electrical contact between the contact 112 of the electronic component 102 and the PCB 104. The trace 116 extends along the major surface 118 of the PCB 104, and the electronic component applique 106 is in contact with the major surface 118, as described above.

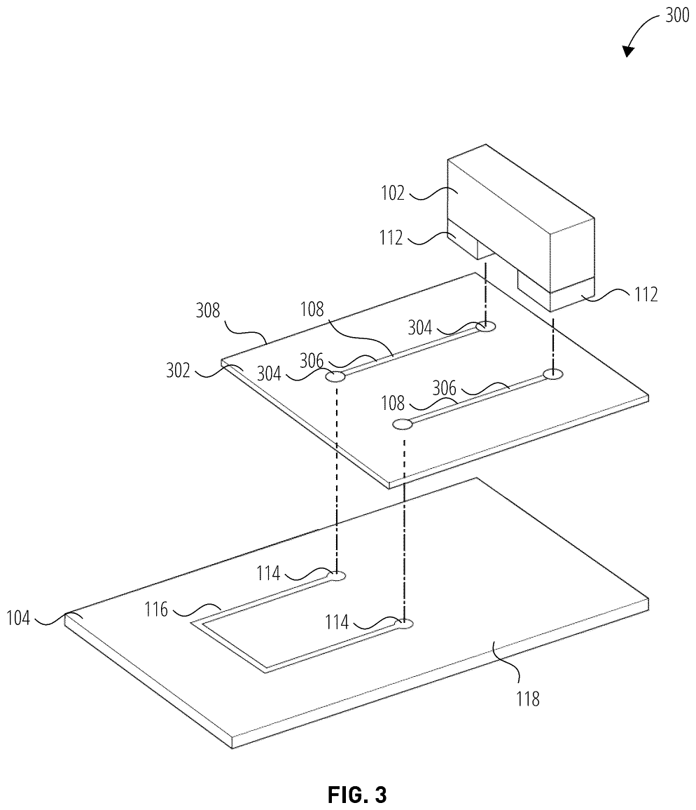

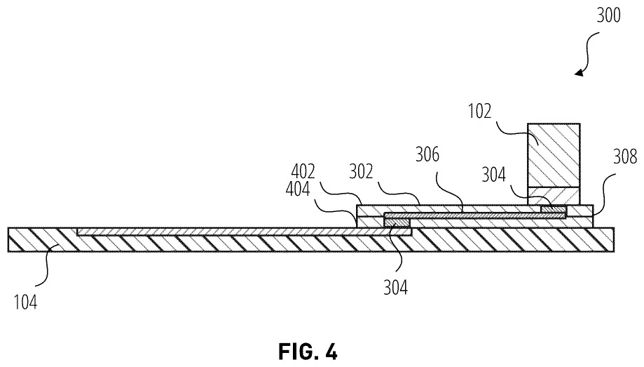

FIG. 3 is an exploded view of an alternative electronic system 300 including the electronic component 102 electrically and mechanically coupled to the PCB 104 with an electronic component applique 302, in an example embodiment. In contrast with the electronic component applique 106 of FIG. 1, the electronic component applique 302 includes conductive gel 108 formed into vias 304 and conductive traces 306 extending between and electrically coupling vias 304 to one another. As will be shown with particularity in FIG. 4, the substrate 308 is comprised of multiple layers to facilitate formation of the vias 304 and conductive traces 306. The layers may be formed according to principles disclosed in U.S. Pat. No. 11,088,063, STRUCTURES WITH DEFORMABLE CONDUCTORS, issued on Aug. 10, 2021, which is incorporated by reference in its entirety. Thus, the conductive gel 108 generally forms relatively more complicated structures than in the electronic component applique 106, thereby allowing greater flexibility on the incorporation of the electronic component 102 with the PCB 104 and into the electronic system 300 generally than may be provided by the electronic component applique 106.

Otherwise, the electronic system 300 functions similarly, with the contacts 112 electrically coupled to an associated one of the vias 304 and the electrical contacts 114 of the PCB 104 electrically coupled to other ones of the vias 304. The trace 116 extends between the electrical contacts 114 and the substrate 308 of the electronic component applique 302 is mechanically coupled to the major surface 118 of the PCB 104 and to the electronic component 102 in the same manner as the electronic component applique 106.

FIG. 4 is a cross-sectional depiction of the electronic system 300, in an example embodiment. As noted above, the electronic component applique 302 includes a substrate 308 formed from a first layer 402, e.g., a top layer, and a second layer 404, e.g., a bottom layer. Each layer 402, 404 may be comprised of the same material as the substrate 110 of the electronic component applique 106 of FIG. 1. As illustrated, each via 304 extends through one layer 402, 404, but not the other. The conductive trace 306 is positioned between the layers 402, 404. In various examples, the conductive gel 108 forms the vias 304 and conductive traces 306 by channels formed in one or more of the layers 402, 404. The layers 402, 404 may thus function to encapsulate the conductive gel 108 to reduce or prevent migration of the conductive gel 108. The electronic component 102 and PCB 104 are otherwise arranged as previously described with respect to FIG. 2.

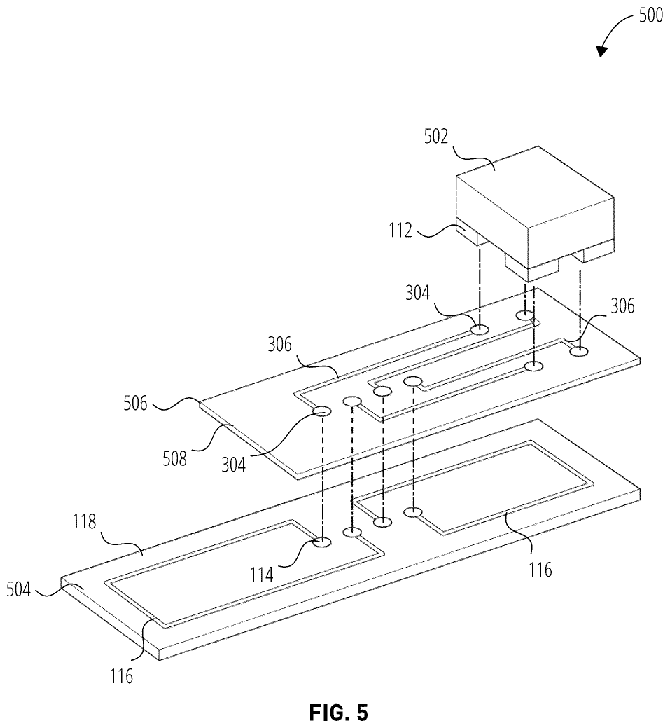

FIG. 5 is an exploded view of an alternative electronic system 300 including an electronic component 502 electrically and mechanically coupled to a PCB 504 with an electronic component applique 506, in an example embodiment. The electronic component applique 506 includes conductive gel 108 formed into vias 304 and conductive traces 306 as with the electronic component applique 302 illustrated in FIG. 3, though with four vias 304 and four conductive traces 306. The electronic component applique 506 is thereby able to support an electronic component 502 with four contacts 112 (one being obscured) rather than two contacts 112, as in the electronic component 102 illustrated in FIG. 1. The PCB 504 similarly incorporates four electrical contacts 114 and multiple traces 116 on the major surface 118.

The substrate 508 of the electronic component applique 506 is formed from multiple layers, e.g., a first layer 402 and a second layer 404 as illustrated in FIG. 4. The substrate 508 may optionally incorporate more than two layers as needed given the number of vias 304 and conductive traces 306. The substrate 508 may be formed from the same materials as the substrate 110 and substrate 308 and be configured to mechanically couple the electronic component 502 to the PCB 504 and, in particular, bond or otherwise adhere to the major surface 118 of the PCB 504.

FIG. 6 illustrates a sheet 602 of electronic component appliques 106, in an example embodiment. The electronic component appliques 106 are illustrated abstractly. It is to be recognized and understood that while the description of the sheet 602 is with respect to the electronic component applique 106, the principles disclosed may be applied to any electronic component applique disclosed herein or that may be developed, as appropriate.

Each electronic component applique 106 is partially separated from adjacent electronic component appliques 106 by a perforation 604 or scoreline. In various examples, the perforation 604 is formed in the substrate 110 (not depicted) of each electronic component applique 106. In such an example, the sheet 602 may be formed with continuous substrate 110 material and each electronic component applique 106 formed by creating the perforation 604 within the substrate 110, thereby creating separate electronic component appliques 106. Each electronic component applique 106 may be individually removed from the sheet 602 and utilized to adhere the electronic component 102 and PCB 104 together and provide the interface therebetween.

In an alternative example, the perforations 604 are not provided. In such an example, the substrates 110 may be formed of continuous material and the electronic component appliques 106 may not be fully separately identifiable while in the sheet 602. In such an example, a given electronic component applique 106 may be cut out or otherwise separated from the sheet 602 by cutting through the substrate 110, e.g., with shears, scissors, or any other suitable cutting instrument

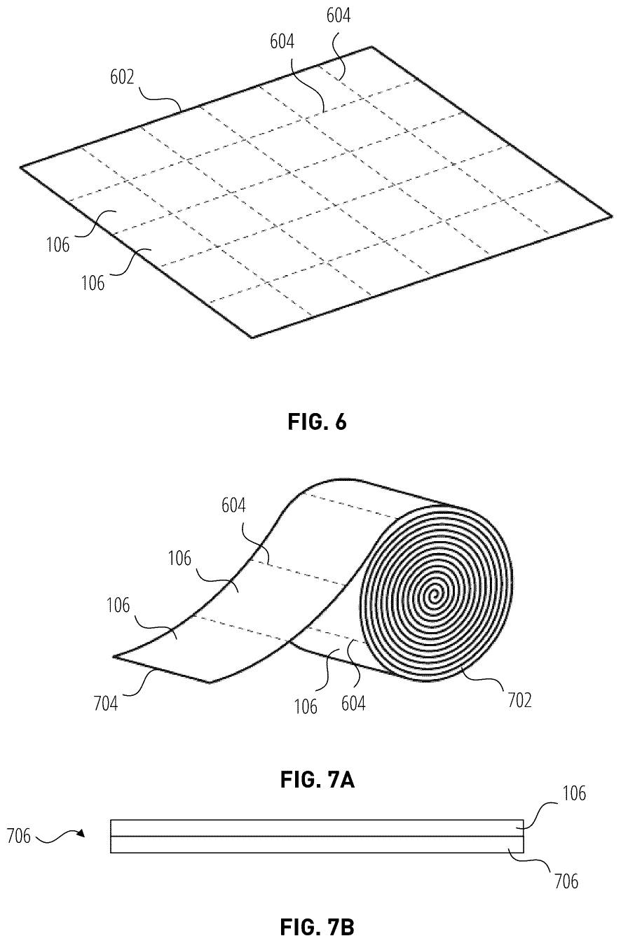

FIG. 7A illustrates a roll 702 of electronic component appliques 106, in an example embodiment. The electronic component appliques 106 are illustrated abstractly. It is to be recognized and understood that while the description of the roll 702 is with respect to the electronic component applique 106, the principles disclosed may be applied to any electronic component applique disclosed herein or that may be developed, as appropriate.

As with the sheet 602 of FIG. 6, each electronic component applique 106 is partially separated from adjacent electronic component appliques 106 by a perforation 604, e.g., in the substrate 110 (not depicted) of each electronic component applique 106. Each electronic component applique 106 may be individually removed from the roll 702, e.g., in sequence starting from an exposed end 704 of the roll 702. Alternatively, the perforations 604 mat not be provided and each electronic component applique 106 may be cut from the roll 702.

FIG. 7B illustrates a side profile of a portion of the roll 702, in an example embodiment. The roll 702 may incorporate one or more release layer 706 positioned on at least one major surface of some or all of the electronic component appliques 106 of the roll 702. The release layer 706 may be a removable sheet that partially or removably adheres to the electronic component applique 106 and may prevent or inhibit one electronic component applique 106 in the roll 702 from coming into contact with another electronic component applique 106 of the roll 702. Contact between electronic component appliques 106 in the roll 702 may over time cause the material of the substrate 110 of each electronic component appliques 106 to flow together or otherwise cause the substrates 110 to become fully or partially adhered to one another. The release layer 706 may also reduce or eliminate migration of the conductive gel 108 (not depicted) of the electronic component appliques 106. While the release layer 706 may have particular relevance to the example of the roll 702, it is to be recognized and understood that one or more release layers 706 may also be applied to the sheet 602 of FIG. 6.

The release layer 706 may be formed from a readily recyclable material. Although siliconized films have been long regarded as difficult to recycle, recent advancements have made recycling of thermoplastic or paper-based films treated with a silicone additive to enhance release. One such method is disclosed in U.S. Pat. No. 8,845,840, which is incorporated herein by reference in its entirety. In such examples, the optional release layer 706 may be selected from a group of readily recyclable materials, e.g., siliconized or non-siliconized PET film, or a paper-based release film (siliconized or non-siliconized).

As used herein, the term “conductive gel” or “deformable conductive material” may refer to a material such as those disclosed in the aforementioned International Patent Application No. PCT/US2017/019762 titled LIQUID WIRE, which was filed on Feb. 27, 2017 and published on Sep. 8, 2017 as International Patent Publication No. WO2017/151523A1, the disclosure of which is herein incorporated by reference in its entirety. For example, a deformable conductive material can include a variety of forms, such as a liquid, a paste, a gel, and/or a powder, amongst others, that has a deformable (e.g., soft, flexible, stretchable, bendable, elastic, flowable viscoelastic, Newtonian, non-Newtonian, etc.) quality.

In various aspects, a deformable conductive material can include an electroactive material, such as a deformable conductor produced from a conductive gel (e.g., made from a gallium indium alloy). The conductive gel can have a shear thinning composition and, according to some aspects, can include a mixture of materials in a desired ratio. The electrically conductive compositions, such as conductive gels, comprised in the articles described herein can, for example, have a paste like or gel consistency that can be created by taking advantage of, among other things, the structure that gallium oxide can impart on the compositions when gallium oxide is mixed into a eutectic gallium alloy. When mixed into a eutectic gallium alloy, gallium oxide can form micro or nanostructures that are further described herein, which structures are capable of altering the bulk material properties of the eutectic gallium alloy.

As used herein, the term “eutectic” generally refers to a mixture of two or more phases of a composition that has the lowest melting point, and where the phases simultaneously crystallize from molten solution at this temperature. The ratio of phases to obtain a eutectic is identified by the eutectic point on a phase diagram. One of the features of eutectic alloys is their sharp melting point.

The electrically conductive compositions can be characterized as conducting shear thinning gel compositions. The electrically conductive compositions described herein can also be characterized as compositions having the properties of a Bingham plastic. For example, the electrically conductive compositions can be viscoplastics, such that they are rigid and capable of forming and maintaining three-dimensional features characterized by height and width at low stresses but flow as viscous fluids at high stress. Thus, for example, the electrically conductive compositions can have a viscosity ranging from about 10,000,000 Pa*s to about 40,000,000 Pa*s under low shear and about 150 Pa*s to 180 Pa*s at high shear. For example, under condition of low shear the composition has a viscosity of about 10,000,000 Pa*S, about 15,000,000 Pa*s, about 20,000,000 Pa*s, about 25,000,000 Pa*s, about 30,000,000 Pa*s, about 45,000,000 Pa*s, or about 40,000,000 Pa*s under conditions of low shear. Under condition of high shear, the composition has a viscosity of about 150 Pa*s, about 155 Pa*s, about 160 Pa*s, 165 Pa*s, about 170 Pa*s, about 175 Pa*s, or about 180 Pa*s.

The electrically conductive compositions described herein can have any suitable conductivity, such as a conductivity of from about 2×10⁵ S/m to about 8×10⁵ S/m.

The electrically conductive compositions described herein can have ay suitable melting point, such as a melting point of from about −20° C. to about 10° C., about −10° C. to about 5° C., about −5° C. to about 5° C. or about −5° C. to about 0° C.

The electrically conductive compositions can comprise a mixture of a eutectic gallium alloy and gallium oxide, wherein the mixture of eutectic gallium alloy and gallium oxide has a weight percentage (wt %) of between about 59.9% and about 99.9% eutectic gallium alloy, such as between about 67% and about 90%, and a wt % of between about 0.1% and about 2.0% gallium oxide such as between about 0.2 and about 1%. For example, the electrically conductive compositions can have about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, about 95%, about 96%, about 97%, about 98%, about 99%, or greater, such as about 99.9% eutectic gallium alloy, and about 0.1%, about 0.2%, about 0.3%, about 0.4%, about 0.5%, about 0.6%, about 0.7%, about 0.8%, about 0.9%, about 1.0%, about 1.1%, about 1.2%, about 1.3%, about 1.4%, about 1.5%, about 1.6%, about 1.7%, about 1.8%, about 1.9%, and about 2.0% gallium oxide.

The eutectic gallium alloy can include gallium-indium or gallium-indium-tin in any ratio of elements. For example, a eutectic gallium alloy includes gallium and indium. The electrically conductive compositions can have any suitable percentage of gallium by weight in the gallium-indium alloy that is between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

The electrically conductive compositions can have a percentage of indium by weight in the gallium-indium alloy that is between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

The eutectic gallium alloy can include gallium and tin. For example, the electrically conductive compositions can have a percentage of tin by weight in the alloy that is between about 0.001% and about 50%, such as about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, or about 50%.

The electrically conductive compositions can comprise one or more micro-particles or sub-micron scale particles blended with the eutectic gallium alloy and gallium oxide. The particles can be suspended, either coated in eutectic gallium alloy or gallium and encapsulated in gallium oxide or not coated in the previous manner, within eutectic gallium alloy. The micro-or sub-micron scale particles can range in size from nanometer to micrometer and can be suspended in gallium, gallium-indium alloy, or gallium-indium-tin alloy. Particle to alloy ratio can vary and can change the flow properties of the electrically conductive compositions. The micro and nanostructures can be blended within the electrically conductive compositions through sonication or other suitable means. The electrically conductive compositions can include a colloidal suspension of micro and nanostructures within the eutectic gallium alloy/gallium oxide mixture.

The electrically conductive compositions can further include one or more micro-particles or sub-micron scale particles dispersed within the compositions. This can be achieved in any suitable way, including by suspending particles, either coated in eutectic gallium alloy or gallium and encapsulated in gallium oxide or not coated in the previous manner, within the electrically conductive compositions or, specifically, within the eutectic gallium alloy fluid. These particles can range in size from nanometer to micrometer and can be suspended in gallium, gallium-indium alloy, or gallium-indium-tin alloy. Particle to alloy ratio can vary, in order to, among other things, change fluid properties of at least one of the alloys and the electrically conductive compositions. In addition, the addition of any ancillary material to colloidal suspension or eutectic gallium alloy in order to, among other things, enhance or modify its physical, electrical or thermal properties. The distribution of micro and nanostructures within the at least one of the eutectic gallium alloy and the electrically conductive compositions can be achieved through any suitable means, including sonication or other mechanical means without the addition of particles. In certain embodiments, the one or more micro-particles or sub-micron particles are blended with the at least one of the eutectic gallium alloy and the electrically conductive compositions with wt % of between about 0.001% and about 40.0% of micro-particles, for example about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, or about 40.

The one or more micro-or sub-micron particles can be made of any suitable material including soda glass, silica, borosilicate glass, quartz, oxidized copper, silver coated copper, non-oxidized copper, tungsten, super saturated tin granules, glass, graphite, silver coated copper, such as silver coated copper spheres, and silver coated copper flakes, copper flakes, or copper spheres, or a combination thereof, or any other material that can be wetted by the at least one of the eutectic gallium alloy and the electrically conductive compositions. The one or more micro-particles or sub-micron scale particles can have any suitable shape, including the shape of spheroids, rods, tubes, a flakes, plates, cubes, prismatic, pyramidal, cages, and dendrimers. The one or more micro-particles or sub-micron scale particles can have any suitable size, including a size range of about 0.5 microns to about 60 microns, as about 0.5 microns, about 0.6 microns, about 0.7 microns, about 0.8 microns, about 0.9 microns, about 1 microns, about 1.5 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, about 26 microns, about 27 microns, about 28 microns, about 29 microns, about 30 microns, about 31 microns, about 32 microns, about 33 microns, about 34 microns, about 35 microns, about 36 microns, about 37 microns, about 38 microns, about 39 microns, about 40 microns, about 41 microns, about 42 microns, about 43 microns, about 44 microns, about 45 microns, about 46 microns, about 47 microns, about 48 microns, about 49 microns, about 50 microns, about 51 microns, about 52 microns, about 53 microns, about 54 microns, about 55 microns, about 56 microns, about 57 microns, about 58 microns, about 59 microns, or about 60 microns.

The electrically conductive compositions described herein can be made by any suitable method, including a method comprising blending surface oxides formed on a surface of a eutectic gallium alloy into the bulk of the eutectic gallium alloy by shear mixing of the surface oxide/alloy interface. Shear mixing of such compositions can induce a cross linked microstructure in the surface oxides; thereby forming a conducting shear thinning gel composition. A colloidal suspension of micro-structures can be formed within the eutectic gallium alloy/gallium oxide mixture, for example as, gallium oxide particles and/or sheets.

The surface oxides can be blended in any suitable ratio, such as at a ratio of between about 59.9% (by weight) and about 99.9% eutectic gallium alloy, to about 0.1% (by weight) and about 2.0% gallium oxide. For example percentage by weight of gallium alloy blended with gallium oxide is about 60%, 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, about 95%, about 96%, about 97%, about 98%, about 99%, or greater, such as about 99.9% eutectic gallium alloy while the weight percentage of gallium oxide is about 0.1%, about 0.2%, about 0.3%, about 0.4%, about 0.5%, about 0.6%, about 0.7%, about 0.8%, about 0.9%, about 1.0%, about 1.1%, about 1.2%, about 1.3%, about 1.4%, about 1.5%, about 1.6%, about 1.7%, about 1.8%, about 1.9%, and about 2.0% gallium oxide. In embodiments, the eutectic gallium alloy can include gallium-indium or gallium-indium-tin in any ratio of the recited elements. For example, a eutectic gallium alloy can include gallium and indium.

The weight percentage of gallium in the gallium-indium alloy can be between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

Alternatively or in addition, the weight percentage of indium in the gallium-indium alloy can be between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

A eutectic gallium alloy can include gallium, indium, and tin. The weight percentage of tin in the gallium-indium-tin alloy can be between about 0.001% and about 50%, such as about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, or about 50%.

The weight percentage of gallium in the gallium-indium-tin alloy can be between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

Alternatively or in addition, the weight percentage of indium in the gallium-indium-tin alloy can be between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

One or more micro-particles or sub-micron scale particles can be blended with the eutectic gallium alloy and gallium oxide. For example, the one or more micro-particles or sub-micron particles can be blended with the mixture with wt % of between about 0.001% and about 40.0% of micro-particles in the composition, for example about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, or about 40. In embodiments the particles can be soda glass, silica, borosilicate glass, quartz, oxidized copper, silver coated copper, non-oxidized copper, tungsten, super saturated tin granules, glass, graphite, silver coated copper, such as silver coated copper spheres, and silver coated copper flakes, copper flakes or copper spheres or a combination thereof, or any other material that can be wetted by gallium. In some embodiments the one or more micro-particles or sub-micron scale particles are in the shape of spheroids, rods, tubes, a flakes, plates, cubes, prismatic, pyramidal, cages, and dendrimers. In certain embodiments, the one or more micro-particles or sub-micron scale particles are in the size range of about 0.5 microns to about 60 microns, as about 0.5 microns, about 0.6 microns, about 0.7 microns, about 0.8 microns, about 0.9 microns, about 1 microns, about 1.5 microns, about 2 microns, about 3 microns, about 4 microns, about 5 microns, about 6 microns, about 7microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, about 26 microns, about 27 microns, about 28 microns, about 29 microns, about 30 microns, about 31 microns, about 32 microns, about 33 microns, about 34 microns, about 35 microns, about 36 microns, about 37 microns, about 38 microns, about 39 microns, about 40 microns, about 41 microns, about 42 microns, about 43 microns, about 44 microns, about 45 microns, about 46 microns, about 47 microns, about 48 microns, about 49 microns, about 50 microns, about 51 microns, about 52 microns, about 53 microns, about 54 microns, about 55 microns, about 56 microns, about 57 microns, about 58 microns, about 59 microns, or about 60 microns.

In various aspects, the conductive gel 108 material may exhibit adhesion to various layers of a circuit assembly and terminal/contacts of an electric component, as determined by the “Smear Test.” The Smear Test may be performed by smearing approximately 1 cm³ of a deformable conductive material on a test coupon of the layer material or the terminal/contact material. The conductive gel 108 material is smeared with a cotton swab (i.e., a Q-Tip™) across the test coupon. If the conductive gel 108 material coats the test coupon without void formation, then the conductive gel 108 material exhibits adhesion to the test coupon material. Conversely, if smearing the conductive gel 108 material to the test coupon causes the conductive gel 108 material to bead, thereby leaving voids on the test coupon, then the conductive gel 108 material does not exhibit adhesion. For example, some formulations of conductive gel 108 materials may have a surface tension that causes the deformable conductive material to bead. The Smear Test should be performed for all materials that have contact interfaces with the deformable conductive material to test for adhesion (e.g., terminals, channels, leads, contact point walls, etc.).

In various aspects, a deformable conductive material can be a non-hazardous material. As used herein, the term “non-hazardous” can mean that a material is RoHS (Restriction of Hazardous Substances) complaint according to European Union Directive 2002/95/EC, Directive 2011/65/EU, and/or Directive 2015/863 (i.e. RoHS, RoHS 2, RoHS 3). For example, in some aspects, a non-hazardous material can include a wt. % of less than 0.01% Cadmium (Cd), less than 0.1% Lead (Pb), less than 0.1% Mercury (Hg), less than 0.1% Hexavalent Chromium (Cr VI), less than 0.1% Polybrominated Biphenyls (PBB), less than 0.1% Polybrominated Diphenyl Ethers (PBDE), less than 0.1% Bis (2-Ethylhexyl) phthalate (DEHP), less than 0.1% Benzyl butyl phthalate (BBP), less than 0.1% Dibutyl phthalate (DBP), and less than 0.1% Diisobutyl phthalate (DIBP).

### EXAMPLES

Example 1 is an applique, comprising: a substrate having an adhesive property; and conductive gel, contained within openings in the substrate; wherein the conductive gel is configured to electrically couple with a first electronic component and a second electronic component to electrically couple the first electronic component to the second electronic component; wherein the adhesive property of the substrate is configured to adhere at least one of the first electronic component and the second electronic component to the substrate.

In Example 2, the subject matter of Example 1 includes, wherein the first electronic component includes a plurality of contacts and wherein the conductive gel is configured to electrically couple with each of the plurality of contacts.

In Example 3, the subject matter of any one or more of Examples 1 and 2 includes, wherein the conductive gel forms a plurality of vias, each of the plurality of vias configured to electrically couple to a different one of the plurality of contacts.

In Example 4, the subject matter of any one or more of Examples 1-3 includes, wherein the plurality of vias extend through the substrate.

In Example 5, the subject matter of any one or more of Examples 1-4 includes, wherein second electronic component comprises a plurality of electrical contacts and wherein each of the plurality of vias are configured to electrically couple to a different one of the plurality of electrical contacts.

In Example 6, the subject matter of any one or more of Examples 1-5 includes, wherein the substrate is comprised of a thermoplastic polyurethane.

In Example 7, the subject matter of any one or more of Examples 1-6 includes, wherein the substrate is comprised of at least one of: a thermoset epoxy-based film and a C-stage resin film.

In Example 8, the subject matter of any one or more of Examples 1-7 includes, wherein the substrate comprises an adhesive film that provides the adhesive property.

In Example 9, the subject matter of any one or more of Examples 1-8 includes, wherein the substrate further comprises a polyimide flex sheet, the adhesive film coupled to the polyimide flex sheet.

In Example 10, the subject matter of any one or more of Examples 1-9 includes, a release layer on at least one major surface of the substrate, the release layer configured to be removed to expose the adhesive property.

Example 11 is a system, comprising: a first electronic component; a second electronic component; and an applique, comprising: a substrate having an adhesive property; and conductive gel, contained within openings in the substrate; wherein the conductive gel is configured to electrically couple with the first electronic component and the second electronic component to electrically couple the first electronic component to the second electronic component; wherein the adhesive property of the substrate is configured to adhere at least one of the first electronic component and the second electronic component to the substrate.

In Example 12, the subject matter of Example 11 includes, wherein the first electronic component includes a plurality of contacts and wherein the conductive gel is configured to electrically couple with each of the plurality of contacts.

In Example 13, the subject matter of any one or more of Examples 11 and 12 includes, wherein the conductive gel forms a plurality of vias, each of the plurality of vias configured to electrically couple to a different one of the plurality of contacts.

In Example 14, the subject matter of any one or more of Examples 11-13 includes, wherein the plurality of vias extend through the substrate.

In Example 15, the subject matter of any one or more of Examples 11-14 includes, wherein second electronic component comprises a plurality of electrical contacts and wherein each of the plurality of vias are configured to electrically couple to a different one of the plurality of electrical contacts.

In Example 16, the subject matter of any one or more of Examples 11-15 includes, wherein the substrate is comprised of a thermoplastic polyurethane.

In Example 17, the subject matter of any one or more of Examples 11-16 includes, wherein the substrate is comprised of at least one of: a thermoset epoxy-based film and a C-stage resin film.

In Example 18, the subject matter of any one or more of Examples 11-17 includes, wherein the substrate comprises an adhesive film that provides the adhesive property.

In Example 19, the subject matter of any one or more of Examples 11-18 includes, wherein the substrate further comprises a polyimide flex sheet, the adhesive film coupled to the polyimide flex sheet.

In Example 20, the subject matter of any one or more of Examples 11-19 includes, a release layer on at least one major surface of the substrate, the release layer configured to be removed to expose the adhesive property.

In Example 21, the subject matter of any one or more of Examples 11-20 includes, wherein the second electronic component is a printed circuit board (PCB) and the adhesive property causes the substrate to adhere to the PCB.

In Example 22, the subject matter of any one or more of Examples 11-21 includes, wherein the first electronic component is a chip package.

Example 23 is an applique, comprising: a substrate comprising a first layer and a second layer and having an adhesive property; and conductive gel, forming: a first via extending through the first layer; a second via extending through the second layer; and a conductive trace formed between the first layer and the second layer and electrically coupled to the first and second vias; wherein the first via is configured to electrically couple with a first electronic component and the second via is configured to electrically couple with a second electronic component to electrically couple the first electronic component to the second electronic component; wherein the adhesive property of the substrate is configured to adhere at least one of the first electronic component and the second electronic component to the substrate.

In Example 24, the subject matter of Example 23 includes, wherein the first via is one of a plurality of first vias formed in the first layer, wherein the first electronic component includes a plurality of contacts, and wherein individual ones of the plurality of first vias are configured to electrically couple with individual ones of the plurality of contacts.

In Example 25, the subject matter of any one or more of Examples 23 and 24 includes, wherein the second via is one of a plurality of second vias formed in the second layer, wherein the second electronic component comprises a plurality of electrical contacts, and wherein individual ones of the plurality of second vias are configured to electrically couple with individual ones of the plurality of electrical contacts to electrically couple individual ones of the plurality of contacts of the first electronic component with individual ones of the plurality of electrical contacts of the second electronic component.

In Example 26, the subject matter of any one or more of Examples 23-25 includes, wherein the first and second layers are comprised of a thermoplastic polyurethane.

In Example 27, the subject matter of any one or more of Examples 23-26 includes, wherein the first and second layers are comprised of at least one of: a thermoset epoxy-based film and a C-stage resin film.

In Example 28, the subject matter of any one or more of Examples 23-27 includes, wherein the substrate comprises an adhesive film that provides the adhesive property.

In Example 29, the subject matter of any one or more of Examples 23-28 includes, wherein the substrate further comprises a polyimide flex sheet, the adhesive film coupled to the polyimide flex sheet.

In Example 30, the subject matter of any one or more of Examples 23-29 includes, a release layer on at least one major surface of the substrate, the release layer configured to be removed to expose the adhesive property.

Example 31 is at least one machine-readable medium including instructions that, when executed by processing circuitry, cause the processing circuitry to perform operations to implement of any of Examples 1-30.

Example 32 is an apparatus comprising means to implement of any of Examples 1-30.

Example 33 is a system to implement of any of Examples 1-30.

Example 34 is a method to implement of any of Examples 1-30.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or any suitable combination thereof), registers, or other machine components that receive, store, transmit, or display information. Furthermore, unless specifically stated otherwise, the terms “a” or “an” are herein used, as is common in patent documents, to include one or more than one instance. Finally, as used herein, the conjunction “or” refers to a non-exclusive “or,” unless specifically stated otherwise.

What is claimed is:

1. An applique, comprising:
a substrate having an adhesive property; and
conductive gel, contained within openings in the substrate;
wherein the conductive gel is configured to electrically couple with a first electronic component and a second electronic component to electrically couple the first electronic component to the second electronic component;
wherein the adhesive property of the substrate is configured to adhere at least one of the first electronic component and the second electronic component to the substrate.

2. The applique of claim 1, wherein the first electronic component includes a plurality of contacts and wherein the conductive gel is configured to electrically couple with each of the plurality of contacts.

3. The applique of claim 2, wherein the conductive gel forms a plurality of vias, each of the plurality of vias configured to electrically couple to a different one of the plurality of contacts.

4. The applique of claim 3, wherein the plurality of vias extend through the substrate.

5. The applique of claim 4, wherein second electronic component comprises a plurality of electrical contacts and wherein each of the plurality of vias are configured to electrically couple to a different one of the plurality of electrical contacts.

6. The applique of claim 1, wherein the substrate is comprised of a thermoplastic polyurethane.

7. The applique of claim 1, wherein the substrate is comprised of at least one of: a thermoset epoxy-based film and a C-stage resin film.

8. The applique of claim 1, wherein the substrate comprises an adhesive film that provides the adhesive property.

9. The applique of claim 1, further comprising a release layer on at least one major surface of the substrate, the release layer configured to be removed to expose the adhesive property.

10. A system, comprising:
a first electronic component;
a second electronic component; and
an applique, comprising:
a substrate having an adhesive property; and
conductive gel, contained within openings in the substrate;
wherein the conductive gel is configured to electrically couple with the first electronic component and the second electronic component to electrically couple the first electronic component to the second electronic component;
wherein the adhesive property of the substrate is configured to adhere at least one of the first electronic component and the second electronic component to the substrate.

11. The system of claim 10, wherein the first electronic component includes a plurality of contacts and wherein the conductive gel is configured to electrically couple with each of the plurality of contacts.

12. The system of claim 11, wherein the conductive gel forms a plurality of vias, each of the plurality of vias configured to electrically couple to a different one of the plurality of contacts.

13. The system of claim 12, wherein the plurality of vias extend through the substrate.

14. The system of claim 13, wherein second electronic component comprises a plurality of electrical contacts and wherein each of the plurality of vias are configured to electrically couple to a different one of the plurality of electrical contacts.

15. The system of claim 10, wherein the substrate is comprised of a thermoplastic polyurethane.

16. The system of claim 10, wherein the substrate is comprised of at least one of: a thermoset epoxy-based film and a C-stage resin film.

17. The system of claim 10, wherein the substrate comprises an adhesive film that provides the adhesive property.

18. The system of claim 10, further comprising a release layer on at least one major surface of the substrate, the release layer configured to be removed to expose the adhesive property.

19. The system of claim 10, wherein the second electronic component is a printed circuit board (PCB) and the adhesive property causes the substrate to adhere to the PCB.

20. The system of claim 10, wherein the first electronic component is a chip package.
